(19) United States
(12) Patent Application Publication
(10) Pub. No.: US 2010/0233627 A1
(43) Pub. Date: Sep. 16, 2010

(54) PHOTOSENSITIVE RESIN COMPOSITION, METHOD FOR FORMING RESIST PATTERN, METHOD FOR MANUFACTURING PRINTED WIRING BOARD, AND METHOD FOR PRODUCING SUBSTRATE FOR PLASMA DISPLAY PANEL

(75) Inventors: Takashi Kumaki, Ibaraki (JP); Masahiro Miyasaka, Ibaraki (JP)

Correspondence Address: GRIFFIN & SZIPL, PC, SUITE PH-1, 2300 NINTH STREET, SOUTH, ARLINGTON, VA, 22204, US

(73) Assignee: Hitachi Chemical Co., Ltd., Tokyo (JP)

(21) Appl. No.: 12/280,247

(22) PCT Filed: Feb. 20, 2007
(86) PCT No.: PCT/JP2007/053045

§ 371 Date: Aug. 21, 2008

(30) Foreign Application Priority Data
Feb. 21, 2006 (JP) 2006-043816
Jun. 16, 2006 (JP) 2006-167674

(51) Int. Cl. G03F 7/20; G03F 7/004

(52) U.S. Cl. 430/286.1; 430/325; 430/313; 430/319

(57) ABSTRACT

A photosensitive resin composition comprising (A) a binder polymer with a weight-average molecular weight of 35000 to 65000, (B) a photopolymerizable compound with an ethylenically unsaturated bond and (C) a photopolymerization initiator, wherein component (B) includes (B1) a photopolymerizable compound with one ethylenically unsaturated bond, (B2) a photopolymerizable compound with two ethylenically unsaturated bonds and (B3) a photopolymerizable compound with three ethylenically unsaturated bonds, and the proportion of component (B3) with respect to the total of component (B) is 15 to 30 wt %.

### TECHNICAL FIELD

The present invention relates to a photosensitive resin composition, a resist pattern forming method, a process for production of a printed circuit board and a process for production of a plasma display panel board.

### BACKGROUND ART

Photosensitive resin compositions are used as resist materials for formation of resist patterns that are to be employed as masks for etching or plating in the manufacture of printed circuit boards. Photosensitive resin compositions are widely used in the form of photosensitive elements which comprise a photosensitive resin composition-containing layer (hereinafter referred to as “photosensitive layer”) on a support film.

Conventional manufacture of printed circuit boards employing such photosensitive elements involves contact bonding a photosensitive element onto a circuit-forming board such as a copper clad laminate while heating, with the photosensitive layer in close contact with the circuit-forming board, and subjecting the photosensitive layer to pattern exposure through a mask film or the like. After exposure, the unexposed sections are removed by dissolution or dispersion in a developing solution to form a resist pattern. A conductor pattern is then formed by etching or plating using the formed resist pattern as a mask. Following formation of the conductor pattern, the resist pattern is removed in the final step.

When a conductor pattern is formed by etching, for example, the copper foil at the sections not covered by the resist pattern are removed by etching and the resist pattern is then released. When the conductor pattern is formed by plating, the plating forms layers of copper, solder or the like on the copper foil at the sections that are not covered by the resist pattern, and then the resist pattern is removed and the copper foil at the sections covered by the resist pattern are removed by etching.

Incidentally, within the field of flat panel displays (hereinafter referred to as “FPD”), plasma display panels (hereinafter referred to as “PDP”) are more popular for OA devices and public display devices because they are capable of higher speed display than liquid crystal panels and are more suitable for large sizes. Further advancement of PDPs for the field of high definition television is also highly anticipated. With such diversifying uses, interest is increasing in regard to color PDPs comprising numerous fine display cells.

PDPs create a display by generating plasma discharge between electrodes in a discharge space formed between a glass panel and a back glass panel, and exposing a phosphor in the discharge space to ultraviolet rays generated from gas sealed within the discharge space. In order to limit the spread of the discharge to a fixed region while ensuring a uniform discharge space, the discharge space is partitioned by “ribs”. The ribs have widths of 20 to 80 μm and heights of 60 to 200 μm.

The method employed for forming the ribs is usually a known sandblast method, screen printing method, photosensitive paste method, photo-casting method or mold transfer method. In addition, the “wet etching process” advocated by Photonics Systems, DuPont and LG Micron has also attracted interest in the SID (Society for Information Display), as a new manufacturing process. In most cases where such ribs are formed, a step is carried out in which the photosensitive resin composition is subjected to pattern exposure.

For pattern exposure, there have been proposed techniques in which a filter is used to cut at least 99.5% of light with a wavelength of 365 nm or smaller from the light emitted from a mercury lamp light source, and the transmitted active light rays used for pattern exposure. In recent years, gallium nitride-based blue laser light sources with long life and high output have become economically available for emission of light with a wavelength of 405 nm, and techniques using such light sources for pattern exposure have also been proposed.

Pattern exposure has conventionally been performed through a photomask using a mercury lamp as the light source, but recently there have been proposed direct writing methods such as DLP (Digital Light Processing) exposure methods (for example, see Non-patent document 1). The light sources employed in these exposure methods are also mercury lamp light sources as active light rays with 99.5% of the light with a wavelength of 365 nm and smaller cut out using a filter, and sometimes blue laser light sources are used.

[Non-patent document 1] Electronics Packaging Technology, June 2002, p. 74-79.

### DISCLOSURE OF THE INVENTION

### Problems to be Solved by the Invention

For improved production throughput it is desirable to shorten the exposure time. The photosensitive resin composition should therefore have high sensitivity. With direct writing methods, it is particularly difficult to ensure high illuminance compared to pattern exposure employing conventional photomasks, and therefore a longer exposure time tends to be necessary.

An appropriate combination of photoinitiator and sensitizing agent can increase the sensitivity of the photosensitive resin composition. When such a combination is used, however, the resolution is lowered and the shape of the formed resist pattern compromised, tending to make it difficult to obtain a regular rectangular cross-sectional shape of the resist pattern. When a conventional photosensitive resin composition is used, therefore, it has not been possible to obtain both high sensitivity and a resist pattern with high resolution and a satisfactory shape.

It is therefore an object of the present invention to provide a photosensitive resin composition that has high sensitivity while allowing formation of resist patterns with high resolution and satisfactory shapes.

### Means for Solving the Problems

In order to achieve the object state above, the present inventors conducted much diligent research on compositions of binder polymers and photopolymerizable compounds, and as a result we have completed this invention upon finding that by using a binder polymer with a weight-average molecular weight in a specified range and combining it with a photopolymerizable compound having a specific composition, it is possible to obtain a photosensitive resin composition with high sensitivity that allows formation of resist patterns with high resolution and satisfactory shapes.

Specifically, the invention provides a photosensitive resin composition comprising (A) a binder polymer with a weight-average molecular weight of 35000 to 65000, (B) a photopolymerizable compound with an ethylenically unsaturated bond and (C) a photopolymerization initiator, wherein component (B) includes (B1) a photopolymerizable compound with one ethylenically unsaturated bond, (B2) a photopolymerizable compound with two ethylenically unsaturated bonds and (B3) a photopolymerizable compound with three ethylenically unsaturated bonds, and the proportion of component (B3) with respect to the total of component (B) is 15 to 30 wt %.

The proportion of component (B2) with respect to the total of component (B) is preferably 40 to 70 wt %. If the proportion of component (B2) is not within this range, the effect of enhanced resolution will tend to be less prominent.

The proportion of component (B1) with respect to the total of component (B) is preferably 15 to 30 wt %. If the proportion of component (B1) is not within this range, development residue will tend to be produced and the effect of enhanced resolution may be impaired.

Component (C) preferably contains 2,4,5-triarylimidazole dimer. This will further improve the adhesiveness and sensitivity of the photosensitive resin composition.

The photosensitive resin composition also preferably contains a sensitizing dye as component (D). This can further increase the sensitivity of the photosensitive resin composition.

In the resist pattern forming method of the invention, the resist pattern is formed by irradiating active light rays onto the photosensitive layer composed of the photosensitive resin composition and then removing a portion of the photosensitive layer.

The process for production of a printed circuit board according to the invention comprises a step of forming a resist pattern by the resist pattern forming method of the invention and a step of forming a conductor pattern by etching or plating using the formed resist pattern as a mask.

The invention further provides a process for production of a plasma display panel board comprising a board and ribs formed on the board, the process comprising a step of forming a resist pattern by the resist pattern forming method of the invention, a step of removing a portion of the rib precursor film using the formed resist pattern as a mask to accomplish patterning, and a step of forming ribs from the patterned rib precursor film.

The photosensitive resin composition of the invention has satisfactory adhesiveness with rib materials used in plasma display panels, and allows high levels of both adhesiveness and resolution to be achieved during manufacture of plasma display panels. The release property from rib materials is also satisfactory. In other words, the photosensitive resin composition of the invention is useful for the manufacture of plasma display panel boards with ribs.

### EFFECT OF THE INVENTION

According to the invention there is provided a photosensitive resin composition that has high sensitivity while allowing formation of resist patterns with high resolution and satisfactory shapes.

Also, the resist pattern forming method of the invention allows formation of resist patterns having shapes with satisfactorily high resolution when using short exposure times.

The process for production of printed circuit boards according to the invention allows high-throughput production of printed circuit boards having conductor patterns formed at high density.

The process for production of plasma display panel boards according to the invention allows high-throughput production of plasma display panel boards having patterned ribs at high density.

### BRIEF DESCRIPTION OF THE DRAWINGS

FIG. 1 is a simplified cross-sectional view showing an example of the resist pattern forming method of the invention.

FIG. 2 is a simplified cross-sectional view showing an example of the process for production of a printed circuit board according to the invention.

FIG. 3 is a simplified cross-sectional view showing an example of the process for production of a plasma display panel board according to the invention.

### EXPLANATION OF SYMBOLS

1: Photosensitive layer, 2: resist pattern, 3: circuit-forming board, 5: surface resin layer, 7: support film, 11: board, 12: board, 15: photosensitive element, 20: conductive layer, 25: conductor pattern, 30: rib precursor film, 35: rib, 100: laminated board, 200: printed circuit board, 300: plasma display panel board.

### BEST MODES FOR CARRYING OUT THE INVENTION

Preferred embodiments of the invention will now be described in detail. However, the present invention is not limited to the embodiments described below. Throughout the present specification, the term “(meth)acrylic acid” means acrylic acid or methacrylic acid, the term “(meth)acrylate” means acrylate or its corresponding methacrylate, and the term “(meth)acryloyl group” means an acryloyl or methacryloyl group.

The photosensitive resin composition according to an embodiment of the invention comprises at least (A) a binder polymer with a weight-average molecular weight of 35000 to 65000, (B) a photopolymerizable compound with an ethylenically unsaturated bond and (C) a photopolymerization initiator. The photosensitive resin composition is suitable for use as a resin to form the photosensitive layer of a photosensitive element having a support film and a photosensitive layer formed on the support film. In this case, the side of the photosensitive layer opposite the support film side will normally be covered with a resin-made protective film. The protective film is appropriately released during formation of the resist pattern.

As binder polymers for component (A) there may be used polymers capable of dissolving or dispersing the other components, such as the photopolymerizable compound. The binder polymer may be composed of a single type of polymer, or a combination of two or more polymers. When it is composed of a combination of two or more polymers, the combination used may be polymers with different copolymerizing components, weight-average molecular weights and degrees of dispersion. There may also be used a polymer having a multimode molecular weight distribution, as described in Japanese Unexamined Patent Publication HEI No. 11-327137.

The weight-average molecular weight (Mw) of the binder polymer is 35000 to 65000. If the Mw is less than 35000, some of the exposed sections of the photosensitive layer will be removed during development, tending to result in flaking off of the lower section of the resist pattern. If the Mw is greater than 65000, on the other hand, the resist pattern will tend to adopt a larger width at the lower section. If the cross-sectional shape of the resist pattern thus becomes no longer regular rectangular, the precision in the step of etching or plating using the resist pattern as a mask will be reduced. From the same viewpoint, the weight-average molecular weight of the binder polymer is more preferably 40000 to 60000 and even more preferably 45000 to 56000.

The degree of dispersion (Mw/Mn) of the binder polymer is preferably 1.0 to 3.0 and more preferably 1.0 to 2.0. A degree of dispersion of greater than 3.0 will tend to lower the adhesiveness and resolution of the photosensitive resin composition.

The weight-average molecular weight (Mw) and number-average molecular weight (Mn) of the binder polymer may be measured by gel permeation chromatography (GPC), calculated with a calibration curve using standard polystyrene.

As examples for the binder polymer there may be mentioned acrylic-based resins, styrene-based resins, epoxy-based resins, amide-based resins, amide/epoxy-based resins, alkyd-based resins, phenol-based resins and the like. From the standpoint of the alkali development property, there may be used an acrylic-based resin containing a (meth)acrylic acid ester as the copolymerizing component. These may be used alone or in combinations of two or more.

The binder polymer preferably comprises a monomer unit derived from styrene or a styrene derivative. Using such a monomer unit will impart the photosensitive layer with satisfactory adhesiveness and release properties with respect to circuit-forming boards. The term “styrene derivative” used above means a compound obtained by substituting a hydrogen atom of styrene with a substituent (an organic group such as alkyl, or a halogen atom). Specific examples of styrene derivatives include vinyltoluene and α-methylstyrene.

From the same viewpoint, the proportion of monomer units derived from styrene or styrene derivatives is preferably 3 to 30 wt %, more preferably 4 to 28 wt % and even more preferably 5 to 27 wt % based on the total weight of the polymer. A proportion of less than 3 wt % will tend to lower the adhesiveness, while a proportion of greater than 30 wt % will tend to impair the release property.

From the viewpoint of adhesiveness and release property, the binder polymer preferably has a monomer unit derived from methacrylic acid. It is most preferred for the binder polymer to be a polymer obtained by copolymerization of methacrylic acid, an alkyl methacrylate ester and styrene.

The binder polymer may be produced, for example, by radical polymerization of a polymerizable monomer. As polymerizable monomers there may be used styrene, styrene derivatives, (meth)acrylic acid alkyl esters, (meth)acrylic acid and the like.

As other polymerizable monomers there may be mentioned acrylamides such as diacetoneacrylamide, acrylonitrile, vinyl alcohol esters such as vinyl-n-butyl ether, tetrahydrofurfuryl(meth)acrylate ester, dimethylaminoethyl(meth)acrylate ester, diethylaminoethyl (meth)acrylate ester, glycidyl(meth)acrylate ester, 2,2,2-trifluoroethyl (meth)acrylate, 2,2,3,3-tetrafluoropropyl(meth)acrylate, α-bromo(meth)acrylic acid, α-chlor(meth)acrylic acid, β-furyl(meth)acrylic acid, β-styryl(meth)acrylic acid, maleic acid, maleic acid monoesters such as maleic acid anhydride, monomethyl malate, monoethyl malate and monoisopropyl malate, and fumaric acid, cinnamic acid, α-cyanocinnamic acid, itaconic acid, crotonic acid, propiolic acid and the like. These may be used alone or in any desired combinations of two or more.

(Meth)acrylic acid alkyl esters are represented by, for example, the following general formula (1). In formula (1), R³ represents hydrogen or a methyl group, and R⁴ represents a C1-12 alkyl group. R⁴ is optionally substituted with hydroxyl, epoxy or a halogen atom.

[Chemical Formula 1]

CH₂═C(R³)—COOR⁴ (I)

As examples of C1-12 alkyl groups represented by R⁴ in formula (1) there may be mentioned methyl, ethyl, propyl, butyl, pentyl, hexyl, heptyl, octyl, nonyl, decyl, undecyl, dodecyl and their structural isomers.

As specific preferred examples of (meth)acrylic acid alkyl esters represented by formula (1) there may be mentioned methyl (meth)acrylate ester, ethyl(meth)acrylate ester, propyl(meth)acrylate ester, butyl(meth)acrylate ester, pentyl(meth)acrylate ester, hexyl (meth)acrylate ester, heptyl(meth)acrylate ester, octyl(meth)acrylate ester, 2-ethylhexyl(meth)acrylate ester, nonyl(meth)acrylate ester, decyl(meth)acrylate ester, undecyl(meth)acrylate ester and dodecyl (meth)acrylate ester. These may be used alone or in any desired combinations of two or more.

The binder polymer preferably contains a polymer with a carboxyl group, in order to ensure a satisfactory developing property when alkali development is carried out using an alkali solution. The polymer with a carboxyl group may be produced by radical polymerization of, for example, a carboxyl group-containing polymerizable monomer and another polymerizable monomer.

When the binder polymer contains a polymer with a carboxyl group, the acid value of the binder polymer is preferably 30 to 200 mgKOH/g and more preferably 45 to 150 mgKOH/g. If the acid value is less than 30 mgKOH/g the developing time will tend to be longer, and if it is greater than 200 mgKOH/g the developing solution resistance of the photocured resist will tend to be reduced.

When an organic solvent is used as the developing solution, it is preferred to use a low proportion of the polymerizable monomer with a carboxyl group in the binder polymer.

The binder polymer may also contain a polymer with a functional group that exhibits photosensitivity for light with a wavelength of 350 to 440 nm.

The photopolymerizable compound of component (B) comprises a plurality of different photopolymerizable compounds with at least one photopolymerizable ethylenically unsaturated bond. Specifically, the photopolymerizable compound may be, for example, an ester of a polyhydric alcohol and an α,β-unsaturated carboxylic acid; a bisphenol A-based (meth)acrylate compound; a compound obtained by reacting an α,β-unsaturated carboxylic acid with a glycidyl group-containing compound; a urethane monomer such as a (meth)acrylate compound with a urethane bond in the molecule; nonylphenoxypolyethyleneoxy acrylate; a phthalic acid-based compound; a (meth)acrylic acid alkyl ester, or the like. These may be used alone or in combinations of two or more.

The photopolymerizable compound comprises (B1) a photopolymerizable compound with an ethylenically unsaturated bond, (B2) a photopolymerizable compound with two ethylenically unsaturated bonds and (B3) a photopolymerizable compound with at least three ethylenically unsaturated bonds. The upper limit for the number of ethylenically unsaturated bonds in component (B3) is preferably about 8.

As examples for component (B1) there may be mentioned 2-ethylhexylpolyethyleneglycol mono(meth)acrylates, pentylpolyethyleneglycol mono(meth)acrylates, isopentylpolyethyleneglycol mono(meth)acrylates, neopentylpolyethyleneglycol mono(meth)acrylates, hexylpolyethyleneglycol mono(meth)acrylates, heptylpolyethyleneglycol mono(meth)acrylates, octylpolyethyleneglycol mono(meth)acrylates, nonylpolyethyleneglycol mono(meth)acrylates, decylpolyethyleneglycol mono(meth)acrylates, undecylpolyethyleneglycol mono(meth)acrylates, dodecylpolyethyleneglycol mono(meth)acrylates, tridecylpolyethyleneglycol mono(meth)acrylates, tetradecylpolyethyleneglycol mono(meth)acrylates, pentadecylpolyethyleneglycol mono(meth)acrylates, hexadecylpolyethyleneglycol mono(meth)acrylates, heptadecylpolyethyleneglycol mono(meth)acrylates, octadecylpolyethyleneglycol mono(meth)acrylates, nonadecylpolyethyleneglycol mono(meth)acrylates, eicosylpolyethyleneglycol mono(meth)acrylates, cyclopropylpolyethyleneglycol mono(meth)acrylates, cyclobutylpolyethyleneglycol mono(meth)acrylates, cyclopentylpolyethyleneglycol mono(meth)acrylates, cyclohexylpolyethyleneglycol mono(meth)acrylates, cyclohexylpolyethyleneglycol mono(meth)acrylates, cyclooctylpolyethyleneglycol mono(meth)acrylates, cyclononylpolyethyleneglycol mono(meth)acrylates, cyclodecylpolyethyleneglycol mono(meth)acrylates, phenoxypolyethyleneoxy(meth)acrylates, phenoxypolyethyleneoxy-polypropyleneoxy (meth)acrylates, octylphenoxyhexaethyleneoxy (meth)acrylate, octylphenoxyheptaethyleneoxy(meth)acrylate, octylphenoxyoctaethyleneoxy(meth)acrylate, octylphenoxynonaethyleneoxy(meth)acrylate, octylphenoxydecaethyleneoxy(meth)acrylate, nonylphenoxypolyethyleneoxy(meth)acrylates, nonylphenoxypolyethyleneoxy-polypropyleneoxy(meth)acrylates and (meth)acrylic group-containing phthalic acid derivatives. These may be used alone or in combinations of two or more. Particularly preferred among those mentioned above are nonylphenoxypolyethyleneoxy(meth)acrylates and (meth)acrylic group-containing phthalic acid derivatives.

As examples of nonylphenoxypolyethyleneoxy(meth)acrylates there may be mentioned nonylphenoxytetraethyleneoxy acrylate, nonylphenoxypentaethyleneoxy acrylate, nonylphenoxyhexaethyleneoxy acrylate, nonylphenoxyheptaethyleneoxy acrylate, nonylphenoxyoctaethyleneoxy acrylate, nonylphenoxynonaethyleneoxy acrylate, nonylphenoxydecaethyleneoxy acrylate and nonylphenoxyundecaethyleneoxy acrylate. These may be used alone or in any desired combinations of two or more.

As (meth)acrylic group-containing phthalic acid derivatives there may be mentioned γ-chloro-β-hydroxypropyl-β′-(meth)acryloyloxyethyl-o-phthalate and β-hydroxyalkyl-β′-(meth)acryloyloxyalkyl-o-phthalate. These may also be used alone or in any desired combinations of two or more.

As examples for component (B2) there may be mentioned 1,6-hexanediol di(meth)acrylate, 1,4-cyclohexanediol di(meth)acrylate, polyethyleneglycol di(meth)acrylates with 2-14 ethylene groups, polypropyleneglycol di(meth)acrylates with 2-14 propylene groups, polyethylene/polypropyleneglycol di(meth)acrylates with 2-14 ethylene groups and 2-14 propylene groups, bisphenol A-based di(meth)acrylates, di(meth)acrylates having a urethane bond in the molecule, bis(acryloxyethyl)hydroxyethyl isocyanurate, bisphenol A diglycidyl ether di(meth)acrylate and (meth)acrylic acid addition products of glycidyl phthalate esters. These may also be used alone or in any desired combinations of two or more.

As bisphenol A-based (meth)acrylate compounds there may be mentioned 2,2-bis[4-((meth)acryloxypolyethoxy)phenyl]propanes, 2,2-bis[4-((meth)acryloxypolypropoxy)phenyl]propanes, 2,2-bis[4-((meth)acryloxypolybutoxy)phenyl]propanes and 2,2-[4-((meth)acryloxypolyethoxypolypropoxy)phenyl]propanes.

As examples of 2,2-bis[4-((meth)acryloxypolyethoxy)phenyl]propanes there may be mentioned 2,2-bis[4-((meth)acryloxydiethoxy)phenyl]propane, 2,2-bis[4-((meth)acryloxytriethoxy)phenyl]propane, 2,2-bis[4-((meth)acryloxytetraethoxy)phenyl]propane, 2,2-bis[4-((meth)acryloxypentaethoxy)phenyl]propane, 2,2-bis[4-((meth)acryloxyhexaethoxy)phenyl]propane, 2,2-bis[4-((meth)acryloxyheptaethoxy)phenyl]propane, 2,2-bis[4-((meth)acryloxyoctaethoxy)phenyl]propane, 2,2-bis[4-((meth)acryloxynonaethoxy)phenyl]propane, 2,2-bis[4-((meth)acryloxydecaethoxy)phenyl]propane, 2,2-bis[4-((meth)acryloxyundecaethoxy)phenyl]propane, 2,2-bis[4-((meth)acryloxydodecaethoxy)phenyl]propane, 2,2-bis[4-((meth)acryloxytridecaethoxy)phenyl]propane, 2,2-bis[4-((meth)acryloxytetradecaethoxy)phenyl]propane, 2,2-bis[4-((meth)acryloxypentadecaethoxy)phenyl]propane and 2,2-bis[4-((meth)acryloxyhexadecaethoxy)phenyl]propane.

Among these, 2,2-bis(4-(methacryloxypentaethoxy)phenyl)propane is commercially available as BPE-500 (product of Shin-Nakamura Chemical Co., Ltd.), and 2,2-bis(4-(methacryloxypentadecaethoxy)phenyl)propane is commercially available as BPE-1300 (product of Shin-Nakamura Chemical Co., Ltd.). The number of ethylene oxide groups per molecule in the aforementioned 2,2-bis[4-((meth)acryloxypolyethoxy)phenyl]propane is preferably 4 to 20 and more preferably 8 to 15. These may be used alone or in any desired combinations of two or more.

As examples of di(meth)acrylate compounds with a urethane bond in the molecule there may be mentioned addition reaction products of (meth)acrylic monomers with an OH group at the β position and diisocyanate compounds (isophorone diisocyanate, 2,6-toluene diisocyanate, 2,4-toluene diisocyanate, 1,6-hexamethylene diisocyanate and the like), as well as tris((meth)acryloxytetraethyleneglycol isocyanate) hexamethyleneisocyanurate, EO-modified urethane di(meth)acrylate, and EO and PO-modified urethane di(meth)acrylate.

As an example of an EO-modified urethane di(meth)acrylate compound there may be mentioned UA-11 (product of Shin-Nakamura Chemical Co., Ltd.).

As an example of an EO,PO-modified urethane di(meth)acrylate compound there may be mentioned UA-13 (product of Shin-Nakamura Chemical Co., Ltd.). These may be used alone or in combinations of two or more.

As examples for component (B3) there may be mentioned trimethylolpropane di(meth)acrylate, trimethylolpropane tri(meth)acrylate, EO-modified trimethylolpropane tri(meth)acrylate, PO-modified trimethylolpropane tri(meth)acrylate, EO,PO-modified trimethylolpropane tri(meth)acrylate, ethyleneoxy-modified tri(meth)acrylates of isocyanuric acid, tri(meth)acrylates with urethane bond derived from isocyanuric acid tetramethylolmethane tri(meth)acrylate, tetramethylolmethane tetra(meth)acrylate, dipentaerythritol penta(meth)acrylate and dipentaerythritol hexa(meth)acrylate. These may be used alone or in combinations of two or more.

Examples of commercially available tri(meth)acrylate compounds with urethane bonds derived from isocyanuric acid include UA-21, UA-41 and UA-42 (all trade names of Shin-Nakamura Chemical Co., Ltd.).

“EO” stands for ethylene oxide, and an EO-modified compound has a block structure of ethylene oxide groups. “PO” stands for propylene oxide, and a PO-modified compound has a block structure of propylene oxide groups.

As examples of photopolymerization initiators as component (C) there may be mentioned aromatic ketones such as 4,4′-(diethylamino)benzophenone, benzophenone and 2-benzyl-2-dimethylamino-1-(4-morpholinophenyl)-nona-1,2-methyl-1-[4-(methylthio)phenyl]-2-morpholino-propanone-1, quinones such as alkylanthraquinones, benzoinether compounds such as benzoinalkyl ether, benzoin compounds such as benzoin and alkylbenzoin, benzyl derivatives such as benzyldimethylketal, 2,4,5-triarylimidazole dimers such as 2-(o-chlorophenyl)-4,5-diphenylimidazole dimer, 2-(o-chlorophenyl)-4,5-(methoxyphenyl)imidazole dimer, 2-(o-fluorophenyl)-4,5-diphenylimidazole dimer, 2-(o-methoxyphenyl)-4,5-diphenylimidazole dimer and 2-(p-methoxyphenyl)-4,5-diphenylimidazole dimer, and acridine derivatives such as 9-phenylacridine and 1,7-(9,9′-acridinyl)heptane.

Particularly preferred among these are 2,4,5-triarylimidazole dimers for further enhanced adhesiveness and sensitivity. The substituents on the aryl groups bonded to the imidazole ring in the 2,4,5-triarylimidazole dimer may be the same or different.

The photosensitive resin composition may also contain a sensitizing dye as component (D). As examples of sensitizing dyes there may be mentioned pyrazolines, anthracenes, coumarins, xanthones, oxazoles, benzooxazoles, thiazoles, benzothiazoles, triazoles, stilbenes, triazines, thiophenes and naphthalimides. Any of these may be used alone or in combinations of two or more.

The content of component (A) is preferably 40 to 80 parts by weight and more preferably 45 to 65 parts by weight with respect to 100 parts by weight as the total of component (A) and component (B). If the content is less than 40 parts by weight the photocured composition may be too fragile, tending to result in inferior coatability when used as a photosensitive element, while if it is greater than 80 parts by weight the sensitivity will tend to be reduced.

The content of component (B) is preferably 20 to 60 parts by weight and more preferably 35 to 55 parts by weight with respect to 100 parts by weight as the total of component (A) and component (B). If the content is less than 20 parts by weight the sensitivity will tend to be reduced, and if it is greater than 60 parts by weight the photocured product will tend to be fragile.

The proportion of component (B1) with respect to the total of component (B) is 15 to 30 wt %. The proportion is preferably 17 to 27 wt % and even more preferably 20 to 25 wt %.

The proportion of component (B2) is preferably 40 to 70 wt %, more preferably 45 to 65 wt % and even more preferably 50 to 60 wt % with respect to the total of component (B).

The proportion of component (B3) is preferably 15 to 30 wt %, more preferably 17 to 27 wt % and even more preferably 20 to 25 wt % with respect to the total of component (B).

The content of the photopolymerization initiator is preferably 0.1 to 10.0 parts by weight, more preferably 0.5 to 6.0 parts by weight and even more preferably 1 to 4 parts by weight with respect to 100 parts by weight as the total of component (A) and component (B). If the proportion is less than 0.1 part by weight the sensitivity will tend to be reduced, while if it is greater than 10.0 parts by weight the curability of the resist bottom section will tend to be reduced and scum will tend to be generated more readily.

The content of the sensitizing dye is preferably 0.01 to 10 parts by weight, more preferably 0.05 to 5 parts by weight and even more preferably 0.1 to 2 parts by weight with respect to 100 parts by weight as the total of component (A) and component (B). A content of less than 0.01 part by weight will tend to prevent satisfactory sensitivity and resolution from being obtained, while a content of greater than 10 parts by weight will make it more difficult to form a satisfactory resist pattern shape.

The photosensitive resin composition may also contain, in addition to the components mentioned above, also photopolymerizable compounds with at least one cationic polymerizable cyclic ether group (oxetane compounds, etc.), cationic polymerization initiators, dyes such as malachite green, photochromic agents such as tribromophenylsulfone and leuco crystal violet, thermal development inhibitors, plasticizers such as p-toluenesulfonamide, pigments, fillers, antifoaming agents, flame retardants, stabilizer, tackifiers, leveling agents, release promoters, antioxidants, aromas, imaging agents, thermal crosslinking agents and the like. The content of these components is preferably about 0.01 to 20 parts by weight with respect to 100 parts by weight as the total of component (A) and component (B). These may be used alone or in combinations of two or more.

The photosensitive resin composition may be used as a solution in a solvent such as methanol, ethanol, acetone, methyl ethyl ketone, methylcellosolve, ethylcellosolve, toluene, N,N-dimethylformamide or propyleneglycol monomethyl ether, or a mixture of such solvents, at a solid content of about 30 to 60 wt %. The solution is used as a coating solution for formation of a photosensitive layer on a photosensitive element. The coating solution may be applied as a liquid resist onto the surface of a metal sheet made of, for example, copper, a copper-based alloy, nickel, chromium, iron, an iron-based alloy such as stainless steel or the like, and preferably onto the surface of copper, a copper-based alloy or an iron-based alloy.

The photosensitive element comprises a support film, a photosensitive layer formed on the support and a protective film covering the side of the photosensitive layer opposite the support.

The support film may be a polymer film having heat resistance and solvent resistance, such as polyethylene terephthalate, polypropylene, polyethylene or polyester, for example. The thickness of the support film is preferably 1 to 100 μm, more preferably 10 to 50 μm and even more preferably 15 to 30 μm. If the thickness is less than 1 μm the support film will be prone to tearing during its release, and if it is greater than 100 μm the resolution will tend to be reduced.

The photosensitive layer is formed by, for example, coating the support film with a solution (coating solution) obtained by dissolving the photosensitive resin composition in a solvent to a solid content of about 30 to 60 wt % and then drying the solution on the support film.

The coating may be accomplished by a publicly known method using, for example, a roll coater, comma coater, gravure coater, air knife coater, die coater, bar coater or the like. The drying may be carried out by heating at 70 to 150° C. for about 5 to 30 minutes.

The amount of residual organic solvent in the photosensitive layer is preferably no greater than 2 wt % from the viewpoint of preventing diffusion of the organic solvent in subsequent steps.

The thickness of the photosensitive layer will differ depending on the use, but the post-drying thickness is preferably 1 to 100 μm and more preferably 1 to 50 μm. A thickness of less than 1 μm will tend to hamper industrial coating, while a thickness of greater than 100 μm will tend to reduce the adhesive force and resolution.

The photosensitive layer preferably has a transmittance of 5 to 75%, more preferably 7 to 60% and most preferably 10 to 40%, for ultraviolet light with a wavelength of 365 nm. A transmittance of less than 5% will tend to result in reduced adhesiveness, while a transmittance of greater than 75% will tend to result in lower resolution. The transmittance may be measured using a UV spectrometer. Model 228A W Beam spectrophotometer by Hitachi, Ltd. may be mentioned as a UV spectrometer.

The protective film is preferably a film such that the adhesive force between the photosensitive layer and protective film is lower than the adhesive force between the photosensitive layer and support. The protective film is also preferably a low fisheye film. “Fisheyes” are contaminants, insoluble matter and oxidative degradation products that become incorporated into films during their production by heat-fusion, kneading, extrusion, biaxial stretching and casting of film materials.

The protective film may be a polymer film having heat resistance and solvent resistance, such as polyethylene terephthalate, polypropylene, polyethylene or polyester, for example. As examples of commercially available products there may be mentioned “ALFAN MA-410” and “E-200C” by Oji Paper Co., Ltd., polypropylene films by Shin-Etsu Film Co., Ltd. or polyethylene terephthalate films of the PS series such as “PS-25” by Teijin, Ltd.

The thickness of the protective film is preferably 1 to 100 μm, more preferably 5 to 50 μm, even more preferably 5 to 30 μm and most preferably 15 to 30 μm. If the thickness is less than 1 μm the protective film will tend to tear more easily during lamination, while if it is greater than 100 μm the cost of the film will be increased.

The photosensitive element may also comprise interlayers such as a cushion layer, adhesive layer, photoabsorbing layer and gas barrier layer as necessary.

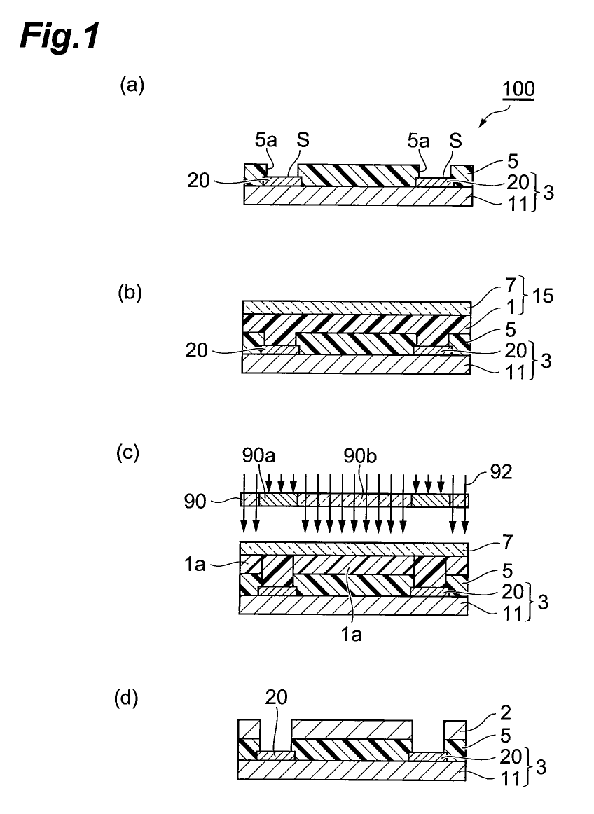

FIG. 1 is a simplified cross-sectional view showing an example of the resist pattern forming method of the invention. This example of the method comprises a step of forming a photosensitive layer 1 on a laminated board 100, a step of irradiating the photosensitive layer 1 with active light rays and a step of removing a portion of the photosensitive layer 1 irradiated with active light rays to form a resist pattern 2.

The laminated board 100 shown in FIG. 1(a) is composed of a circuit-forming board 3 comprising a board 11 and a conductive layer 20 formed on the board 11, and a surface resin layer 5 formed on the side of the circuit-forming board 3 opposite the conductive layer 20. The conductive layer 20 is patterned in such a manner to form a prescribed pattern. The surface resin layer 5 is patterned in such a manner that an opening 5a is formed that exposes the surface S of the conductive layer 20.

A photosensitive element 15 comprising a support film 7 and the photosensitive layer 1 formed on the support film 7 is laminated with the photosensitive layer 1 in close contact with the surface of the surface resin layer 5 side of the laminated board 100, thus forming a photosensitive layer 1 on the laminated board 100 (FIG. 1(b)). When the photosensitive element has a protective film, the protective film is released from the photosensitive layer before lamination. The photosensitive element 15 is preferably laminated by contact bonding while heating. More specifically, the photosensitive element 15 and/or laminated board 100 are preferably heated at 70 to 130° C. and pressed at about 0.098 to 0.98 MPa (about 1 to 10 kgf/cm²) during the lamination. The laminated board 100 may also be preheated before contact bonding. However, there is no particular restriction to these conditions. In order to achieve satisfactory adhesiveness and follow-up properties of the photosensitive layer 1 for the laminated board 100, it is preferred for the lamination to be carried out under reduced pressure.

Next, the photosensitive layer 1 formed on the laminated board 100 is irradiated with active light rays in the form of an image through a mask pattern 90 (FIG. 1(c)). The irradiation with active light rays forms a cured layer 1a by curing of the photosensitive resin composition at the sections of the photosensitive layer 1 that have been exposed to the active light rays. The light source 92 for the active light rays may be a publicly known light source such as, for example, a carbon arc lamp, mercury vapor arc lamp, high-pressure mercury lamp, xenon lamp or the like, which efficiently emits ultraviolet rays or visible light. The mask pattern 90 is a negative or positive mask pattern known as “artwork”, and it comprises blocking sections 90a that block the active light rays 92 and transparent sections 90b that transmit active light rays 92.

When the support film 7 is transparent to the active light rays, the active light rays may be irradiated with the support film 7 laminated thereover. When the support film 7 is non-transparent to the active light rays, the photosensitive layer 1 is irradiated with the active light rays after its removal.

Instead of a method using a mask pattern as described above, the active light rays may be irradiated into an image form by a direct writing method such as laser direct writing exposure or DLP (Digital Light Processing) exposure.

After irradiation of the active light rays, the sections of the photosensitive layer 1 other than the cured layer 1a are removed to form a resist pattern 2. The method for removing the sections other than the cured layer 1a may be a method of development by wet development, dry development or the like after removal of the support film 7. Wet development is carried out by a known process such as spraying, reciprocal dipping, brushing or scrapping, using a developing solution. The developing solution may be appropriately selected from among aqueous alkali solutions, aqueous developing solutions, organic solvent-based developing solutions and the like, according to the solubility of the photosensitive resin composition.

An aqueous alkali solution is preferred as the developing solution. As bases for the aqueous alkali solution there may be used, for example, alkali hydroxides (hydroxides of lithium, sodium, potassium and the like), alkali carbonates (carbonates or bicarbonates of lithium, sodium, potassium, ammonium and the like), alkali metal phosphates (potassium phosphate, sodium phosphate and the like), and alkali metal pyrophosphates (sodium pyrophosphate, potassium pyrophosphate and the like).

As specific examples of aqueous alkali solutions there may be mentioned a 0.1 to 5 wt % sodium carbonate dilute solution, a 0.1 to 5 wt % potassium carbonate dilute solution, a 0.1 to 5 wt % sodium hydroxide dilute solution or a 0.1 to 5 wt % sodium tetraborate dilute solution.

The pH of the aqueous alkali solution is preferably in the range of 9 to 11, and the temperature is appropriately adjusted as appropriate for the developing property of the photosensitive layer 1.

The aqueous alkali solution may also contain added surfactants, antifoaming agents, and small amounts of organic solvents to accelerate development.

An aqueous developing solution used may be a developing solution composed of water and an aqueous alkali solution or one or more different organic solvents. As examples of bases for aqueous alkali solutions other than those already referred to above there may be mentioned borax, or sodium metasilicate, tetramethylammonium hydroxide, ethanolamine, ethylenediamine, diethylenetriamine, 2-amino-2-hydroxymethyl-1,3-propanediol, 1,3-diaminopropanol-2, morpholine and the like.

The pH of the aqueous developing solution is preferably as low as possible within a range that permits sufficient development of the resist. Specifically, the aqueous developing solution is preferably at pH 8 to 12 and more preferably at pH 9 to 10.

As examples of organic solvents in the aqueous developing solution there may be mentioned acetone, ethyl acetate, alkoxyethanols with C1-4 alkoxy groups, ethyl alcohol, isopropyl alcohol, butyl alcohol, diethyleneglycol monomethyl ether, diethyleneglycol monoethyl ether, diethyleneglycol monobutyl ether and the like. They may be used alone or in combinations of two or more.

The concentration of the organic solvent is normally preferred to be 2 to 90 wt %, and the temperature may be adjusted as appropriate for the developing property of the photosensitive layer 1.

The aqueous developing solution may also contain a small amount of a surfactant, antifoaming agent or the like.

As examples of organic solvent-based developing solutions there may be mentioned 1,1,1-trichloroethane, N-methylpyrrolidone, N,N-dimethylformamide, cyclohexanone, methyl isobutyl ketone and Y-butyrolactone. Such organic solvents preferably contain water in a range of 1 to 20 wt % for anti-flammability.

Two or more different developing methods may also be carried out in combination if necessary. The developing system may be a dip system, paddle system, spray system, brushing, slapping or the like, but a high-pressure spray system is most suitable for improved resolution.

After development, curing of the resist pattern can be accelerated by heating at about 60 to 250° C. or exposure at about 0.2 to 10 J/cm², as necessary.

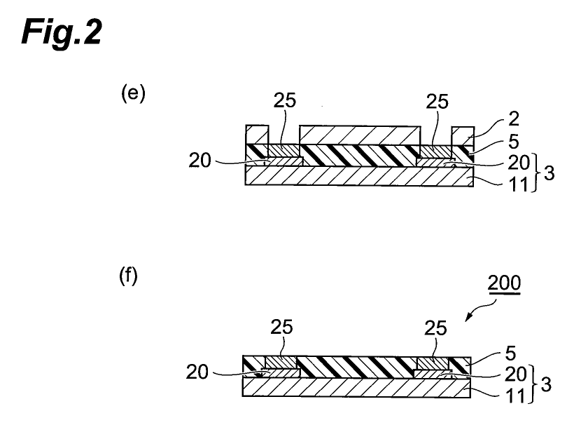

FIG. 2 is a simplified cross-sectional view showing an example of the process for production of a printed circuit board according to the invention. This example of the process comprises a step of forming a resist pattern 2 by the resist pattern forming method described above, a step of forming a conductor pattern 25 by plating using the formed resist pattern 2 as a mask (FIG. 2(e)), and a step of removing the resist pattern 2 (FIG. 2(f)).

The plating process may be, for example, copper plating such as copper sulfate plating or copper pyrophosphate plating, solder plating such as high throwing solder plating, nickel plating such as Watt bath (nickel sulfate-nickel chloride) plating or nickel sulfaminate plating, or gold plating such as hard gold plating or soft gold plating.

Instead of using plating to form the conductor pattern on the patterned conductive layer as in this example, the conductor pattern may be formed by removing a portion of the conductive layer by etching with the resist pattern as the mask.

In this case, the etching solution is preferably a cupric chloride solution, ferric chloride solution, alkali etching solution or hydrogen peroxide etching solution. A ferric chloride solution is preferred among those mentioned above from the viewpoint of achieving a satisfactory etch factor.

After the conductor pattern 25 has been formed, the resist pattern 2 is removed to obtain a printed circuit board 200. The resist pattern 2 is then removed by, for example, release using an aqueous solution of stronger alkalinity than the aqueous alkali solution used for development. The strongly alkaline aqueous solution used here may be, for example, a 1 to 10 wt % sodium hydroxide aqueous solution or a 1 to 10 wt % potassium hydroxide aqueous solution.

The releasing system may be, for example, a dipping system, spray system or the like. A dipping system or spray system may be used alone, or they may be used in combination.

The production process of the invention can be applied as a process for production of a multilayer printed circuit board and small through-holes.

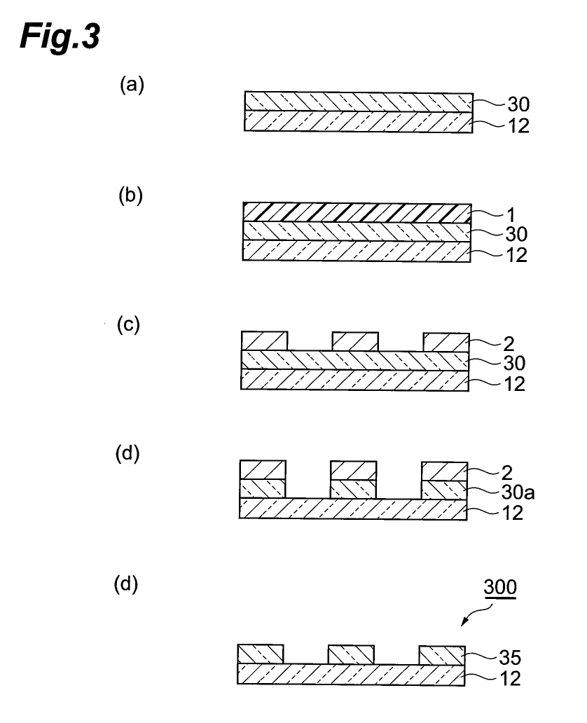

FIG. 3 is a simplified cross-sectional view showing an example of the process for production of a plasma display panel board according to the invention. This example of the process comprises a step of forming a resist pattern 2 on a rib precursor film 30 formed on a board 12, a step of removing a portion of the rib precursor film 30 using the resist pattern 2 as a mask for patterning, a step of removing the resist pattern 2 and a step of forming ribs 35 from the patterned rib precursor film 30a.

For this example, first the rib precursor film 30 is formed on the board 12 (FIG. 3(a)). The board 12 may be a transparent board such as a glass panel. The rib precursor film 30 is formed by shaping a film from a rib precursor that produces a rib material by firing or the like. The rib precursor is appropriately selected from among materials that are ordinarily used to form ribs in the field of plasma display panel production. As a specific example of a rib precursor there may be mentioned paste containing glass particles, such as GLASS PASTE PD200 (product of Asahi Glass Co., Ltd.).

The photosensitive layer 1 is formed on the rib precursor film 30 (FIG. 3(b)), and the resist pattern 2 is formed by the same method used to form the resist pattern 2 described above (FIG. 3(c)).

Next, etching is performed using the resist pattern 2 as a mask, and the portions of the rib precursor film 30 not covered by the resist pattern 2 are removed (FIG. 3(d)). This results in formation of a patterned rib precursor film 30a.

The method of etching may be a sandblast method or wet etching process. For a sandblast method, shaved particles of silica or alumina, for example, are blown onto the rib precursor film 30 for etching. For a wet etching process, an acid solution of nitric acid or the like is used for the etching.

The etching is followed by removal of the resist pattern 2. The resist pattern 2 may be removed by the same method as in the process for production of a printed circuit board as described above.

The patterned rib precursor film 30a is then fired to form ribs 35. Thus, a plasma display panel board 300 is obtained that comprises the board 12 and ribs 35 formed on the board 12. The plasma display panel board 300 may be suitably used as the rear board for a plasma display panel.

### EXAMPLES

The present invention will now be explained in greater detail by examples. However, the present invention is not limited to the examples described below.

1. Starting Materials

(A) Binder Polymer

Binder polymers were synthesized with weight-average molecular weights (Mw)=34000, 38000, 46200, 50500, 55000, 64000 and 67000. The copolymerization ratio of each of the binder polymers was methacrylic acid/methyl methacrylate/butyl methacrylate/styrene=25/45/5/25 (weight ratio) (acid value: 160 mgKOH/g). Each obtained binder polymer was dissolved in a mixed solvent comprising methylcellosolve/toluene=3/2 (weight ratio) to obtain a binder polymer solution, which was used to prepare a photosensitive resin composition.

The weight-average molecular weight (Mw) of the binder polymer may be measured by gel permeation chromatography (GPC) under the following conditions, calculated with a calibration curve using standard polystyrene.

GPC conditions

Pump: Hitachi L-6000 (Hitachi, Ltd.)

Column: Gelpack GL-R420+Gelpack GL-R430+Gelpack GL-R440 (total: 3) (all trade names of Hitachi Chemical Co., Ltd.)

Eluent: tetrahydrofuran

Measuring temperature: Room temperature

Flow rate: 2.05 mL/min

Detector: Hitachi L-3300 RI (Hitachi, Ltd.)

(B) Photopolymerizable Compound

(B1)

LITE ACRYLATE NP-8EA (trade name of Kyoeisha Chemical Co., Ltd.): Nonylphenoxypolyethylene glycol acrylate represented by chemical formula (1a) below.

“FA-MECH” (trade name of Hitachi Chemical Co., Ltd.): 2-[(2-Methyl-1-oxoallyl)oxy]ethyl-3-chloro-2-hydroxypropylphthalic acid represented by Chemical Formula (1b) below.

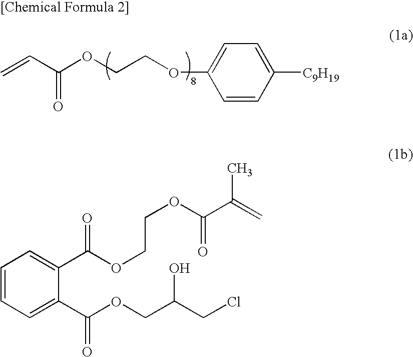

(B2)

“FA-321 M” (trade name of Hitachi Chemical Co., Ltd.): Ethoxylated bisphenol dimethacrylate represented by Chemical Formula (2a) below, with m+n of 10 as average.

“DA-721” (trade name of Nagase ChemteX Corp.): Phthalic acid derivative-epoxy acrylate represented by Chemical Formula (2b) below.

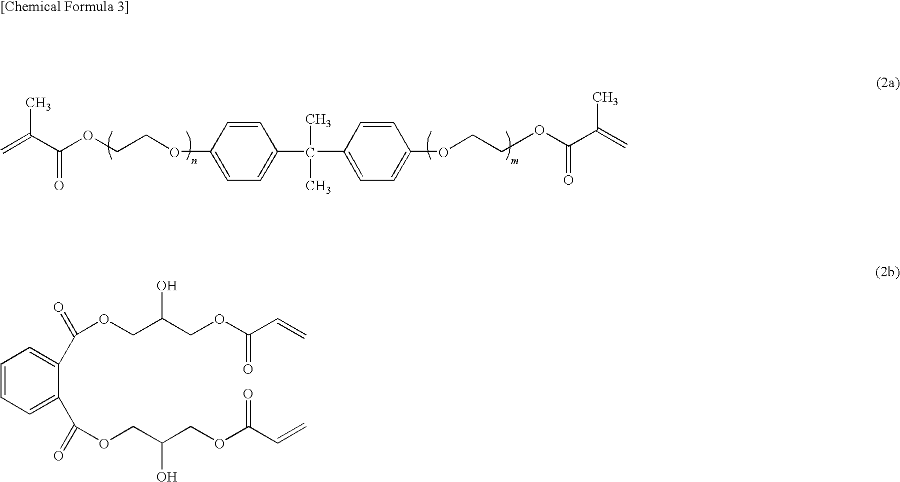

[In formula (2a), m and n both represent positive integers.]

(B3)

“TMPT21” (trade name of Hitachi Chemical Co., Ltd.): Polyhydroxyethyl etherified trimethylolpropane triacrylate represented by Chemical Formula (3a) below.

“NK OLIGO UA-21” (trade name of Shin-Nakamura Chemical Co., Ltd.): Isocyanate/methacrylate ester represented by Chemical Formula (3b) below.

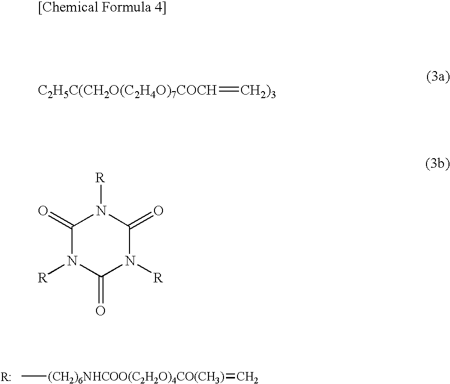

(C) Photopolymerization Initiator

“BCIM”: 2,2′-bis(2-Chlorophenyl)-4,4′,5,5′-tetraphenylbisimidazole

(Other Components)

Sensitizing dye: “PIR1”: 1-Phenyl-3-(4-t-butylstyryl)-5-(4-t-butylphenyl)-pyrazoline
Coloring agent

Leuco crystal violet

### Dye

Malachite green

### Solvent

Mixed solvent comprising 9 g of acetone, 5 g of toluene and 5 g of methanol.

2. Preparation of Photosensitive Resin Composition

In the mixed solvent mentioned above there were dissolved 113 g of a binder polymer solution (54 g solid content), 3.7 g of a photopolymerization initiator, 0.25 g of a sensitizing dye, 0.25 g of a coloring agent and 0.03 g of a dye, with a photopolymerizable compound of the type and amount listed in Table 2, to prepare a solution of a photosensitive resin composition.

3. Preparation of Photosensitive Element

The photosensitive resin composition solution prepared in the manner described above was uniformly coated onto a support film (polyethylene terephthalate film, 16 μm thickness, trade name: “HTF01” by Teijin, Ltd.), and dried with a hot air convection current drier at 70° C. and 110° C. to form a photosensitive layer composed of the photosensitive resin composition. A protective film was attached thereto covering the photosensitive layer to obtain a photosensitive element. The film thickness of the photosensitive layer was 25 μm.

The absorbance (OD value) of the photosensitive layer of each obtained photosensitive element was measured using a UV spectrometer (“U-3310 spectrophotometer”, trade name of Hitachi, Ltd.). Measurement of the OD value was accomplished by removing the protective film from the measuring side of the photosensitive element, placing a support film on the reference side, and performing continuous measurement in a range of 600 to 300 nm in absorbance mode.

4. Evaluation of Photosensitive Element

(1) Sensitivity

The copper foil surface of a copper clad laminate (MCL-E-67 by Hitachi Chemical Co., Ltd.) comprising a glass epoxy material laminated with a copper foil (35 mm thickness) on both sides was polished using a polishing machine equipped with a #600-equivalent brush (Sankei Co., Ltd.), and after cleaning with water, it was dried with an air stream.

The polished copper clad laminate was heated to 80° C. and then the photosensitive element was laminated onto the copper clad laminate while removing the protective film, with the photosensitive layer in close contact with the surface of the copper clad laminate. The lamination was accomplished by pressing the photosensitive element and copper clad laminate at 0.392 MPa (4 kgf/cm²) while heating to 120° C.

The photosensitive element-laminated copper clad laminate was cooled, and upon reaching 23° C., there were contact bonded onto the support film a phototool having a 41-step tablet with a density range of 0 to 2.00, a density step of 0.05, a tablet size of 20 mm×187 mm and a step size of 3 mm×12 mm, and as a negative for evaluation of the resolution, a wiring pattern having a line width/space width of 6/6 to 35/35 (units: mm).

Next, an SCF-100S-39 L Sharp Cut Filter by Sigma Koki Co., Ltd. for 405 nm wavelength exposure was placed thereover and a parallel light exposure system (EXM-1201, product of Orc Manufacturing Co., Ltd.) with a 5 kW short arc lamp light source was used for exposure at an exposure dose for 17 remaining steps after development of the 41-step tablet.

The exposure dose for 17 remaining steps after development of the 41-step tablet was recorded as the sensitivity of the photosensitive layer. An ultraviolet illuminometer (trade name: “UIT-150” with “UVD-S405” (photodetector) by Ushio Inc.) with a 405 nm probe was used to measure the illuminance, and the exposure dose was calculated as illuminance×exposure time.

For direct-writing exposure, the exposure may be performed in the same manner using a DE-1AH by Hitachi Via Mechanics, Ltd., for example. In this case, no phototool is necessary since direct exposure is employed. Since the light source is a 405 nm LD (laser diode), there is also no need to use a sharp cut filter.

Following exposure, the support film is released and 1 wt % aqueous sodium carbonate is sprayed at 30° C. for 24 seconds to remove the unexposed sections.

(2) Release Property

Electrolytic copper plating under the conditions shown in Table 1 was carried out to form a 20 μm-thick copper plating film on the copper foil of the copper clad laminate on which the resist pattern had been formed by the method described above to a 40 micron pitch (L/S=20/20 μm). A 30 wt % sodium hydroxide aqueous solution was also used to release the resist pattern, under the conditions shown in Table 1. The resist pattern that remained without being released was then observed with a metallurgical microscope to evaluate the release property.

TABLE 1

| Process | Conditions |
|---|---|
| Electrolytic | Dipping, air agitation |
| copper plating | 6 wt % aqueous copper sulfate/10 vol % sulfuric acid |
| | 1.6 A/dm², 25 min, 25° C. |
| Release | Release solution (Solution temperature: 50° C., |
| | spray pressure: 0.20 MPa, release time: 60 sec) |

(3) Resolution

The resolution was evaluated as the smallest value of the line width/space width (L/S) at the produced sections which allowed clean removal of the unexposed sections by developing treatment and produced lines without waviness or breaking. A smaller value indicates superior resolution.

(4) Resist Shape

The shape of the resist pattern after development was observed using a Hitachi S-500A Scanning Electron Microscope. The developed resist pattern preferably has a nearly rectangular cross-sectional shape. The cross-sectional shape of the resist pattern loses its regular rectangularity when development occurs in such a way that produces areas of “edge erosion” where the resist pattern has partially chipped at the lower section of the resist pattern, or “edge residue” where a portion of the resist remains at the unexposed sections or where the lower section of the resist pattern has not been removed.

TABLE 2

| | | Example | | | | | | | | | |
|---|---|---|---|---|---|---|---|---|---|---|---|
| | | 1 | 2 | 3 | 4 | 5 | 6 | 7 | 8 | 9 | 10 |
| (A) | Mol. wt. | 56000 | 50500 | 55000 | 55000 | 55000 | 55000 | 55000 | 55000 | 38000 | 64000 |
| | (Mw) | | | | | | | | | | |
| (B1) | NP-8EA | 10 | 10 | 10 | 10 | 10 | | 13 | 7 | 10 | 10 |
| | FA-MECH | | | | | | 10 | | | | |
| (B2) | FA-321M | 25 | 25 | 25 | 25 | | 25 | 20 | 32 | 25 | 25 |
| | DA-721 | | | | | 25 | | | | | |
| (B3) | TMPT-21 | 11 | 11 | 11 | | | | 13 | 7 | 11 | 11 |
| | UA-21 | | | | 11 | 11 | 11 | | | | |
| | Proportion | 24 | 24 | 24 | 24 | 24 | 24 | 28 | 15 | 24 | 24 |
| | (wt %)* | | | | | | | | | | |

| | | | | | | | | | | |
|---|---|---|---|---|---|---|---|---|---|---|
| Absorbance (405 nm) | 0.55 | 0.55 | 0.55 | 0.55 | 0.55 | 0.55 | 0.55 | 0.55 | 0.55 | 0.55 |
| Sensitivity (mJ/cm²) | 60 | 60 | 60 | 60 | 60 | 60 | 60 | 60 | 55 | 65 |
| Release property | Good | Good | Good | Good | Good | Good | Good | Good | Good | Good |
| Resolution | 35/35 | 35/35 | 35/35 | 35/35 | 35/35 | 35/35 | 35/35 | 35/35 | 35/35 | 35/35 |
| Resist shape | Rectan- | Rectan- | Rectan- | Rectan- | Rectan- | Rectan- | Rectan- | Rectan- | Rectan- | Rectan- |
| | gular | gular | gular | gular | gular | gular | gular | gular | gular | gular |

*Proportion with respect to total amount of component (B).

TABLE 3

| | | Comp. Ex. | | | |
|---|---|---|---|---|---|
| | | 1 | 2 | 3 | 4 |
| (A) | Mol. wt. (Mw) | 34000 | 55000 | 46200 | 67000 |
| (B1) | NP-8EA | 10 | 5 | 15 | 10 |
| | FA-MECH | | | | |
| (B2) | FA-321M | 25 | 24 | 27 | 25 |
| | DA-721 | | | | |
| (B3) | TMPT-21 | 11 | 15 | 3 | 11 |
| | UA-21 | | | | |
| | Proportion | 24 | 34 | 6.7 | 24 |
| | (wt %)* | | | | |

| | | | | |
|---|---|---|---|---|
| Absorbance (405 nm) | 0.55 | 0.44 | 0.45 | 0.55 |
| Sensitivity (mJ/cm²) | 55 | 60 | 60 | 65 |
| Release property | Good | Release | Release | Good |
| | | remnants | remnants | |
| Resolution | 35/35 | 50/50 | 40/40 | 50/50 |
| Resist shape | Edge | Edge | Edge | Edge |
| | erosion | erosion | erosion | residue |

*Proportion with respect to total amount of component (B).

As shown in Table 2, Examples 1 to 10 were adequately superior in terms of both resolution and resist shape. In contrast, Comparative Examples 1 and 4 which had binder polymers with weight-average molecular weights in the range of 35000 to 65000, and Comparative Examples 2 and 3 which had component (B3) proportions in the range of 15 to 30 wt %, were inferior to the examples in terms of both resolution and resist shape. It was thus confirmed that the invention provides photosensitive resin compositions with improved resolution and resist shapes while maintaining sufficiently high sensitivity.

1. A photosensitive resin composition comprising:
(A) a binder polymer with a weight-average molecular weight of 35000 to 65000;
(B) a photopolymerizable compound with an ethylenically unsaturated bond; and
(C) a photopolymerization initiator,
wherein component (B) includes:
(B1) a photopolymerizable compound with one ethylenically unsaturated bond;
(B2) a photopolymerizable compound with two ethylenically unsaturated bonds; and
(B3) a photopolymerizable compound with three ethylenically unsaturated bonds, and the proportion of component (B3) with respect to the total of component (B) is 15 to 30 wt %.

2. A photosensitive resin composition according to claim 1,
wherein the proportion of component (B2) with respect to the total of component (B) is 40 to 70 wt %.

3. A photosensitive resin composition according to claim 1,
wherein the proportion of component (B1) with respect to the total of component (B) is 15 to 30 wt %.

4. A photosensitive resin composition according to claim 1,
wherein component (C) contains a 2,4,5-triarylimidazole dimer.

5. A photosensitive resin composition according to claim 1,
which further comprises (D) a sensitizing dye.

6. A resist pattern forming method comprising the steps of:
forming a resist pattern by irradiating active light rays onto a photosensitive layer composed of a photosensitive resin composition according to claim 1; and then
removing a portion of the photosensitive layer.

7. A process for production of a printed circuit board, the process comprising the steps of:
forming a resist pattern by the resist pattern forming method of claim 6; and
forming a conductor pattern by etching or plating using the formed resist pattern as a mask.

8. A process for production of a plasma display panel board comprising a board and ribs formed on the board, the process comprising the steps of:
forming a resist pattern on the rib precursor film formed on the board, by the resist pattern forming method of claim 6;
removing a portion of the rib precursor film using the formed resist pattern as a mask to accomplish patterning; and
forming ribs from the patterned rib precursor film.
